(19) United States
(12) Patent Application Publication
(10) Pub. No.: US 2025/0315117 A1
(43) Pub. Date: Oct. 9, 2025

(54) POWER MANAGEMENT SYSTEMS SUPPORTING PEAK POWER DRIVE MODES OF BATTERY-OPERATED ACCESSORY DEVICE HAPTIC MODULES

(71) Applicant: Apple Inc., Cupertino, CA (US)

(72) Inventors: Eileen A. Funk, Santa Cruz, CA (US); Shingo Yoneoka, San Jose, CA (US); Riccardo Tarelli, Redwood City, CA (US); Robert M. Proie, Aldie, VA (US)

(21) Appl. No.: 19/097,835

(22) Filed: Apr. 1, 2025

Related U.S. Application Data
(60) Provisional application No. 63/574,022, filed on Apr. 3, 2024.

(51) Int. Cl. G06F 3/038; G06F 1/28; G06F 3/01; G06F 3/0354; H02M 3/04; H05K 5/00

(52) U.S. Cl. CPC G06F 3/0383; G06F 1/28; G06F 3/016; G06F 3/03545; H05K 5/0086; H02M 3/04

(57) ABSTRACT

A small form factor electronic device includes a power management system for preventing brownout conditions when driving a haptic element from a small size battery with high internal resistance. The power management system includes a high capacity output capacitor to supplement power output capacity of a current-limiting boost converter receiving as input a constant voltage from a battery.

### CROSS-REFERENCE TO RELATED APPLICATIONS

This application is a nonprovisional and claims the benefit under 35 U.S.C. § 119 (e) of U.S. Provisional Patent Application No. 63/574,022, filed Apr. 3, 2024, the contents of which are incorporated herein by reference as if fully disclosed herein.

### TECHNICAL FIELD

Embodiments described herein relate to drive electronics supporting haptic modules for battery-operated electronic devices and, in particular, to drive electronics supporting haptic module drive modes that exceed power output capacity of a battery-operated electronic device battery.

### BACKGROUND

Electronic devices can include haptic modules to provide mechanical feedback to a user operating the device. Many haptic modules include an air core or solid core coil in order to generate a magnetic field to displace a permanent magnet coupled to a weighted mass, either by rotation or translation. Such elements are low impedance electrical components that, if driven by a constant-voltage power supply such as a battery, demand significant instantaneous current in peak power modes.

However, small form factor electronic devices are typically equipped with batteries that cannot support peak power modes of haptic modules without dropping voltage. In many cases, the voltage drop undershoots minimum voltage requirements of one or more circuits or subsystems, resulting in damage and/or performance-reducing brownout conditions.

### SUMMARY

Embodiments described herein can take the form of an electronic device including at least a housing, a haptic element within the housing, a battery within the housing, and a power management system within the housing. The power management system can include a current-limiting voltage regulator (e.g., a boost converter, boost-buck converter, and the like) coupled to an output of the battery and configured to provide a constant voltage supply rail as output. An output of the voltage regulator is coupled to an output capacitor separate from any output capacitors of the voltage regulator such that the output capacitor couples the constant voltage supply rail to system ground. The system further includes a waveform generator conductively coupled to the output capacitor and the voltage regulator, the waveform generator configured to generate a voltage waveform to drive the haptic element. In these embodiments, a capacity of the output capacitor is selected so as to prevent the constant voltage supply rail from dropping below a threshold voltage when the haptic element may be driven by the voltage waveform.

Some embodiments described herein take the form of an accessory device for providing input to a portable electronic device. The accessory device can include a haptic module with a low impedance drive element such as an electromagnetic coil. The accessory device can also include a battery and a power management system. As with other embodiments described herein, the power management system includes a current-limiting voltage regulator coupled to an output of the battery that is configured to provide a constant voltage supply rail as output. The constant voltage supply rail is in turn coupled to, and provides input voltage to, the processor of the accessory device. In addition, the power management system includes an output capacitor coupling the constant voltage supply rail to system ground and configured to prevent the constant voltage supply rail from dropping below an input voltage threshold of the processor. The power management system can further include a signal generator (such as a Class D amplifier) receiving supply voltage from the output capacitor and configured to generate a voltage signal as output to drive the low impedance drive element of the haptic module.

Some embodiments described herein take the form of a method of driving a haptic module. The method can include the operations of: receiving a first constant voltage from a battery as input to a current-limiting boost converter; providing a second constant voltage from the boost converter, the second constant voltage selected to exceed a minimum voltage requirement of a processor conductively coupled to the second constant voltage output; charging an output capacitor with the second constant voltage; providing voltage across the output capacitor as supply voltage to a Class D amplifier; providing output of the Class D amplifier as input to a haptic module; and causing the Class D amplifier to provide an output voltage signal to drive the haptic module.

### BRIEF DESCRIPTION OF THE DRAWINGS

Reference will now be made to representative embodiments illustrated in the accompanying figures. It should be understood that the following descriptions are not intended to limit this disclosure to one included embodiment. To the contrary, the disclosure provided herein is intended to cover alternatives, modifications, and equivalents as may be included within the spirit and scope of the described embodiments, and as defined by the appended claims.

FIG. 1 depicts a battery-operated accessory device operating to provide input to another portable electronic device.

FIG. 2 depicts a system diagram of a battery-operated electronic device incorporating a haptic module.

FIG. 3 depicts a system diagram of a battery-powered accessory input device incorporating a haptic module and a power management system as described herein.

FIG. 4 depicts an example battery-powered accessory device including a power management system configured to drive a haptic module at peak power.

FIG. 5 depicts a simplified schematic diagram of a battery-operated electronic device power system supporting peak power drive modes of a haptic module.

FIG. 6 depicts a simplified schematic diagram of a battery-operated electronic device power system supporting peak power drive modes of a haptic module.

The use of the same or similar reference numerals in different figures indicates similar, related, or identical items.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Embodiments described herein relate to power management in portable electronic devices and, in particular, to systems for providing peak power output to haptic output modules in power constrained electronic devices such as battery-powered electronic devices having a small form factor.

Small form factor electronic devices (e.g., wearable devices, handheld accessory devices, and the like) have limited enclosure or housing volume in which to dispose a battery. As a result, batteries that can be included within such devices are of limited capacity. As known to a person of skill in the art, limited capacity batteries are often associated with high internal resistance. As a result, a low-capacity battery such as those incorporated into small form factor electronic devices may be incapable or unsuitable to drive a low impedance element such as an electromagnetic coil without (1) incurring permanent damage from overdrawing, or (2) temporarily dropping system-wide battery voltage significantly.

More simply, output capacity of a battery may be characterized in terms of power, the product of voltage and current. Because a battery is a constant voltage supply having an inherent internal resistance that limits current carrying capacity, the battery will supply substantially constant voltage unless and until drawn current causes output power to reach the maximum power output capacity of the battery. Thereafter, as current continues to increase, maximum power output remains the same, necessitating a drop in voltage proportional to the overdraw of current. In some circumstances, overdraw can lead to overheating, battery damage, potential battery expansion and accelerated off-gassing. In other cases, the voltage drop associated with current overdraw causes brownout conditions and/or out-of-specification operations for circuitry and subsystems receiving supply voltage from the battery, potentially causing data loss, reboot loops, performance discontinuities, or other undesirable and unexpected behaviors.

As a result of these possible negative effects, battery-powered electronic devices with small form factors typically do not include low impedance elements, the operation of which may cause current overdraw and voltage drops. A low-impedance element, such as a large-size electromagnetic coil, can draw significant instantaneous current, causing a voltage drop and/or other possibly negative results described above.

For example, a stylus is an example of a battery-powered accessory device with a small form factor that may likewise include a small size battery with high internal resistance. The stylus can include a processor, a memory, analog front ends associated with sensors or sensing systems, signal generators (e.g., for locating a stylus relative to a display surface of another electronic device) and/or one or more wireless communication modules (such as a Bluetooth module) all of which cooperate to perform the expected functions of the stylus device. In addition, however, each of these electronics and their associated analog circuitry are conductively coupled to and receive supply voltage from the battery. In some cases, such digital electronics are coupled directly to the battery; in other cases, a voltage regulation circuit (more simply, a “voltage regulator”) interposes supply rails and the battery, such as a boost converter or a buck converter. In many embodiments, a voltage regulator may be a boost converter. A boost converter topology may be selected so that a constant and stable voltage supply can be provided as a supply rail to each digital circuit while the internal battery of the stylus discharges over time and reduces output voltage capacity.

In conventional constructions of such a stylus, it may not be possible to incorporate a low-impedance element, such as a haptic feedback module due to power output capacity constraints of the battery. More generally, a haptic output module with a size selected so as to not overdraw the battery when actuated may not provide a suitable haptic response to justify its inclusion. Larger size (higher power draw) haptic modules may well provide a suitable haptic response at the expense of overdrawing the battery in certain conditions. In these examples, triggering a haptic output may induce brownout conditions that cause the processor, memory, and/or communications modules to reboot, restart, or otherwise suffer a performance degradation impacting user experience. In worse cases (excluding permanent damage to batteries or electronic components), the processor may power cycle causing the communications module to disconnect and/or to power cycle as well. In these examples, a significant performance interruption may be experienced by the user immediately following an attempted haptic output.

Another example accessory device is a wearable electronic device. As with the prior example stylus, the wearable electronic device may have a housing of limited internal volume that can only accommodate a battery of particular size. The internal resistance of the battery correspondingly limits the potential maximum haptic output that can be provided by a haptic module. It may be desirable, in some cases, to leverage more power to generate a haptic output but as with the stylus example, maximum power output is limited by battery capacity. In this example, the wearable electronic device may reboot or disconnect from other devices or services.

Another example accessory device is a trackpad device that includes a haptic module to mimic depression of a physical button upon an application of clicking force by a user of the trackpad device. As with prior examples, a trackpad may be volumetrically constrained and thus internal batteries may likewise have a lower than desired peak power delivery capacity. As with other examples, the trackpad device may disconnect or become unresponsive if brownout conditions occur.

In yet other examples, an accessory device may be a wireless earbud device worn by a user. In such examples, the wireless earbud may have exceptionally constrained volume and a very small capacity battery. In such applications, inclusion of haptic elements or other low impedance electric circuits may not be possible. In these examples, a wearer of the wireless earbud device may experience playback interruption if brownout conditions occur.

In view of the foregoing, it may be appreciated that generally and broadly battery-powered electronic devices that adopt a small form factor have power output limitations established by the battery itself. These power output limitations typically take the form of maximum current draw, but in some cases in which a low-impedance element exceeds designed current limitations, voltage output of the battery may drop, which can cause brownout conditions, out of specification operation or performance, or other possibly negative user experiences.

Embodiments described herein relate to power management systems for battery-powered electronic devices that increase peak power delivery capacity for driving low impedance elements, such as haptic modules. A person of skill in the art may appreciate that many low impedance elements can be powered from power management systems as described herein, however, for simplicity of illustration and description, the embodiments that follow reference a haptic module as an example low impedance element, although it may be appreciated that this is merely one example.

Similarly, it may be appreciated that many battery-powered electronic devices can leverage power management systems (and low impedance elements) as described herein. Example battery-powered electronic devices include, without limitation: laptop devices; tablet devices; stylus devices; wearable devices (including watches, head-mounted devices, personal displays, glasses devices, earbud devices, chest-mounted devices, and the like); trackpad devices; cursor devices; personal assistant devices; home automation devices; health monitor devices; and so on. For simplicity of description, the embodiments that follow reference a stylus device as an example small form factor battery-powered electronic device but it may be appreciated that this is merely one example.

In view of the foregoing, it is appreciated that the embodiments described herein relate to a stylus device incorporating a haptic module, but this is a nonlimiting example. The haptic module can include a low impedance element. A person of skill in the art may appreciate that many haptic modules or elements can include different types of low impedance (high current draw) elements, an example of which is an electromagnetic coil configured to motivate rotation or displacement of a weighted mass.

Application of a voltage across leads of an electromagnetic coil completes a circuit to induce a current proportional to the input impedance, thereby generating a magnetic field that can interact with nearby ferromagnetic structures. In some constructions, the coil can be positioned to retract or repel a permanent magnet coupled to a spring. In these examples, a magnitude of current circulating the coil corresponds to a magnitude of attraction or repulsion, and, by extension, a magnitude of perceivable haptic effect. More simply, in many constructions, an increase in current consumption by the haptic module (specifically, by an electromagnetic coil within the haptic module) corresponds to an increase in haptic magnitude.

For simplicity of description and illustration, the stylus embodiments described herein are described as having an architecture that incorporates a haptic module implemented with a linear actuator including an electromagnetic coil that attracts or repeals a mass. Changes in momentum of the mass, motivated by a magnetic field generated by the electromagnetic coil, can be perceived by a holder of the stylus as forces acting on the stylus itself.

For example, if the axis of translation of the linear actuator within a stylus is aligned with a longitudinal axis of the stylus, a user holding the stylus may perceive a force acting along that axis to pull the stylus away from a writing surface or to push the stylus into the writing surface. In other cases, the linear actuator may be actuated in a manner that mimics a button press or other engagement with an interface element of a graphical user interface of a tablet device with which the stylus is used. In these cases, the linear actuator may be driven in a manner to provide a sensation of a physical button press, including a first haptic output provided to simulate a button press and a second haptic output provided to simulate a button release. In yet other cases, the linear actuator can be actuated continuously during use of the stylus to emulate a writing surface texture, such as a texture of paper, parchment, canvas, or the like. In these examples, the linear actuator may be actuated in a manner that corresponds to one or more of the location, speed, pressure and so on with which a user leverages the stylus to provide input to a secondary electronic device, such as a tablet or laptop computer.

In other cases, a haptic module can include a linear actuator organized in a different orientation relative to a longitudinal axis of a stylus device. For example, the actuator can be positioned relative to an expected grip position of a hand grasping the stylus body (i.e., nearby a tip of the stylus), and configured to generate a haptic output of perceivable force perpendicular to the longitudinal axis. Many constructions are possible.

It is appreciated however, that a linear actuator is a single non-limiting example of a haptic module that can benefit from power management systems as described herein. In other cases, a haptic module including a different low impedance element can be architected in a different manner, leveraging Lorenz force, gyroscopic procession, magnetic attraction, rotation, or another technique to provide haptic output.

For simplicity of description, the embodiments that follow reference a construction in which a haptic module of a stylus device includes a linear actuator oriented to provide haptic output parallel to a longitudinal axis of the stylus.

A stylus as described herein includes a power management system configured to support peak power output modes of a haptic module. More particularly, a haptic module can be actuated with maximum (or greater than) system voltage—thereby providing maximum haptic output—without risking brownout conditions for other circuits or systems of the stylus device.

In particular, a stylus as described herein is powered by a battery (or more than one battery) coupled to a voltage regulator such as a boost converter. The voltage regulator is a current-limiting voltage regulator to provide over-draw protection to the battery of the stylus device, thereby preventing voltage drop that may effect other circuits of the stylus device. The boost converter can regulate voltage output from the battery such that as the battery discharges, voltage output from the boost converter remains substantially constant. In some cases, a boost buck converter may be used to reduce voltage when the battery is at full capacity and to increase voltage when the battery is at reduced capacity. The embodiments described herein contemplate a construction in which the battery is a rechargeable battery (either via conductive coupling or inductive coupling to another power source) but this is not required of all embodiments; in some cases, non-rechargeable batteries may be used.

As described herein, a current-limiting boost converter (or other current-limiting voltage regulator topology) provides a current-limited, constant voltage stable supply rail for one or more digital or analog circuits. In many examples, these circuits can include a low impedance element of a haptic element, such as described herein. Other circuits that can receive power from a battery of a stylus device (that may be protected form voltage dropping as a result of over-draw) include processors, memory, communications modules (e.g., Bluetooth, Wi-Fi, ultra-wideband, and so on), electric field generators, motions sensors, charging circuits and the like.

The stable supply rail provided as output by the boost converter can be coupled to a high capacity output capacitor coupling the supply rail to system ground. In many embodiments, the output capacitor is distinct from, and separate from, an output capacitor of the voltage regulator. In some examples, the output capacitor may have a capacity of 50-60 μF. In other cases, the output capacitor may have a capacity grater than 25 μF. In some embodiments, the output capacitor may have a capacity of 60 μF or more. Capacity of the output capacitor can vary from embodiment to embodiment. In many cases, the output capacitor can have a cylindrical cross section so as to be suitably disposed within a cavity of a cylindrical stylus housing, although this is not required of all embodiments.

The output capacitor can provide a second supply rail providing a reference voltage for a waveform/signal generator. The signal generator can be configured to provide a voltage signal as output that is configured to be received as input by an electromagnetic coil configured to motivate rotation or displacement of a weighted mass to provide a haptic output. An example signal generator is a Class D amplifier. Another example signal generator may be a digital to analog converter. Further examples may be appropriate in other embodiments.

As a result of this construction in which a large capacity output capacitor interposes stable output provided by a boost converter/voltage regulator and a signal generator, the signal generator can drive the haptic module with maximum supply line voltage to provide haptic feedback. In some cases, the signal generated by the signal generator can be a static voltage signal for a period of time (e.g., a square wave). In other cases, an input-shaped waveform may be generated to cause the mass to displace a particular distance without significant or perceivable ringdown. In other cases, a waveform may be generated to cause several sequential perceivable haptic events, such as a vibration, a double-click, or the like. A person of skill in the art may appreciate any arbitrary waveform can be generated by the signal generator, limited only by a voltage envelope defined by the voltage output of the voltage regulator and the output capacitor. Furthermore, it may be appreciated that different outputs of the signal generator can cause different haptic effects depending upon the structure of the haptic module itself.

In this manner, the output capacitor provides an energy storage apparatus supporting the constant voltage output of the current-limiting boost converter so that the haptic output module can be operated at peak power independent of instantaneous power requirements of other circuits of the stylus device. More specifically, the current-limiting boost converter provides a buffer that prevents over-draw of the battery, while the output capacitor provides an energy reserve for supporting peak power demands of the haptic output module.

The embodiments described herein may be particularly applicable to, and useful for, small form factor electronic devices leveraging surface mount or otherwise integrated boost converters and waveform generators to accommodate size constraints. Furthermore, it may be appreciated that in many cases, it may not be suitable to increase an existing output capacitor of a boost converter, as doing so may cause the voltage feedback controlling operation of the boost converter to be unstable.

In addition, as may be appreciated by persons of skill in the art, many boost converters or other voltage regulation circuits (especially for small form-factor electronic devices) have current limits that may not be suitable for instantaneous current consumption requirements of haptic modules; embodiments described here overcome this limitation and enable actuation of haptic modules at peak power despite current limitations of batteries and/or associated voltage regulation circuitry.

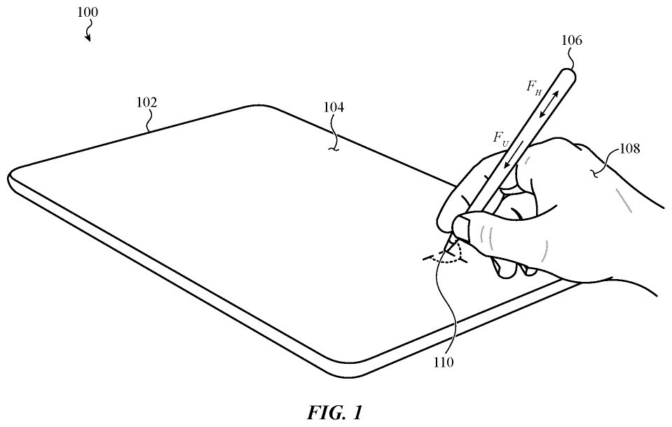

These foregoing and other embodiments are discussed below with reference to FIGS. 1-6. However, those skilled in the art will readily appreciate that the detailed description given herein with respect to these figures is for explanation only and should not be construed as limiting.

FIG. 1 depicts a battery-operated accessory device operating to provide input to another portable electronic device. The user input system 100 includes an electronic device 102 that is illustrated as a tablet device. In other cases the electronic device 102 can be implemented as any other suitable electronic device, whether portable or stationary. Example electronic devices include laptop devices, tablet devices, accessory input devices (e.g., trackpads, mice) and the like.

The electronic device 102 can include a housing to enclose and support components thereof. The electronic device 102 can include a processor, a memory, one or more network communications modules such as Wi-Fi, a cellular modem, or a Bluetooth module. In many cases, the electronic device 102 can include a display that defines a display surface 104.

The processor in many embodiments can be configured to cooperate with the memory to load from the memory an executable asset including an executable instruction. The processor can perform a function in response to the instruction that causes the processor and memory to instantiate an instance of software, such as an operating system or an application instance executing over an operating system. The instance of software can be configured in many embodiments to leverage the display to render a graphical user interface below the display surface 104.

The display can, in many examples, include one or more user input systems such as a touch input system and/or a position coordination engine. The touch input system can be a capacitive sensor array configured to locate positions of one or more points of contact of a users finger with the display surface 104. The position coordination engine can be configured to detect a particularly modulated electrical field transmitted from a tip portion of a stylus input device 106 placed in contact with the display surface 104 by a user 108.

Specifically, the position coordination engine of the electronic device 102 can be configured to interoperate with a corresponding position coordination engine within the stylus input device 106 that emits an electric field from a tip 110 of the stylus input device 106. In response to detecting the field, the position coordination engine of the electronic device 102 can determine a position and orientation of the stylus input device 106 relative to the display surface 104. In some cases, the position coordination engines of the electronic device 102 and the stylus input device 106 can be configured to emit two separate fields, the relative detections of each may be used by the electronic device 102 to determine an angular position of the stylus input device 106 relative to a normal vector defined from the display surface 104.

In other cases, the electronic device 102 and the stylus input device 106 can communicably couple in another manner to provide position and/or angle information of the stylus input device 106 to the electronic device 102; many constructions and techniques are possible.

In many cases, the electronic device 102 and the stylus input device 106 can be communicably coupled via one or more communication channels beyond respective communications of position coordination engines. For example, the electronic device 102 and the stylus input device 106 can be coupled via a Bluetooth low energy communication channel so that the two devices can exchange further information. For example, the stylus input device 106 may communicate battery status information to the electronic device 102 and/or position or angular information as detected by an accelerometer or gyroscope within the stylus input device 106. In some cases, the stylus input device 106 can include a force sensor within the tip 110 that can be sampled at an interval to transmit applied pressure information to the electronic device 102. The electronic device 102 in turn can leverage the pressure information for supplemental user input, such as an indication that the user 108 intends to select a particular affordance rendered in the graphical user interface or that the user 108 intends that a drawn line should have increased thickness. Many use cases for transmitting information from the stylus input device 106 to the electronic device 102 are possible in various applications of the embodiments described herein.

In other cases, the electronic device 102 can provide instructions to the stylus input device 106 to enter a low power mode, to power down, and/or to provide a haptic feedback via a haptic feedback module.

In such examples, the stylus input device 106 can include a power management system and haptic module as described in respect of other embodiments described herein. In particular, the haptic module can include a linear actuator having an axis of motion aligned with longitudinal axis of the stylus input device 106. In this construction, actuation of the haptic module can provide a haptic force Fn that aligns with or opposes a user's application of force Fu through the stylus input device 106 and applied to the display surface 104.

The haptic module can be actuated in response to an instruction provided by the stylus input device 106 or by an instruction provided by the electronic device 102. For example, the application instance executing over a processor and memory of the electronic device 102 can include one or more graphical user interface element, such as free-form input areas and buttons or other input affordances. In response to an input by the user 108 via the stylus input device 106 to an input button (e.g., positioning the stylus input device 106 over the affordance and applying a downward force so as to increase the user force Fu), the electronic device 102 can provide an instruction to the stylus input device 106 to cause the haptic module therein to produce a haptic feedback to give an impression to the user 108 of engaging a physical button.

In other cases, such as while the user 108 positions the stylus input device 106 over a free-form input area rendered within the graphical user interface, force information sampled from a force sensor mechanically coupled to the tip 110 can be used to augment and/or modulate a constant haptic feedback provided via the haptic feedback module. For example, haptic feedback may be caused by a processor of the stylus input device 106 to increase in magnitude in response to and/or proportional to an increase in force applied by the user 108 to the display surface 104.

In some examples, the electronic device 102 can transmit to the stylus input device 106 an indication or other identifier that identifies a particular haptic effect from a library of haptic effects of which the haptic module is capable. For example, the electronic device 102 may transmit via Bluetooth to the stylus input device 106 an integer value that the stylus input device 106 can provide as input to a lookup table stored in a memory of the stylus input device 106, based on information retrieved from the lookup table, the stylus input device 106 can select a particular waveform to generate. In some cases, instructions from the electronic device 102 can include both a haptic feedback identifier and one or more parameters of the associated haptic feedback. For example, an indicator may indicate a simple vibration and an amplitude or gain factor can indicate a magnitude or amplitude of the resulting waveform applied as drive input to the linear actuator of the haptic module. More simply, in some embodiments, the electronic device 102 can be configured to instruct both a haptic output type and one or more parameters of that haptic output. For simplicity of description, different identified haptic output types or predetermined waveforms that can be “played back” by a haptic module at an time in response to an instruction from the electronic device 102 or the stylus input device 106 can be referred to as “playback assets” or more simply, stored “assets.”

Further to the foregoing, an instructed playback of a particular asset can be modified or augmented by the stylus input device 106 itself. For example, in some cases, the stylus input device 106 can be configured to select an amplitude of a particular asset based on a current state of a sensor within the stylus input device 106, such as a force sensor mechanically coupled to the tip 110, a position sensor, an angular sensor, and so on.

In some examples, a particular asset may be designed to require maximum power output. In such constructions, a power management system as described herein may be leveraged to prevent brownout conditions.

These foregoing embodiments depicted in FIG. 1 and the various alternatives thereof and variations thereto are presented, generally, for purposes of explanation, and to facilitate an understanding of various configurations and constructions of a user input system, such as described herein. However, it will be apparent to one skilled in the art that some of the specific details presented herein may not be required in order to practice a particular described embodiment, or an equivalent thereof.

Thus, it is understood that the foregoing and following descriptions of specific embodiments are presented for the limited purposes of illustration and description. These descriptions are not targeted to be exhaustive or to limit the disclosure to the precise forms recited herein. To the contrary, it will be apparent to one of ordinary skill in the art that many modifications and variations are possible in view of the above teachings.

For example, generally and broadly, it may be appreciated that a battery powered electronic device as described herein (e.g., the stylus input device 106 of FIG. 1) can include a power management system that supports operation of a haptic module.

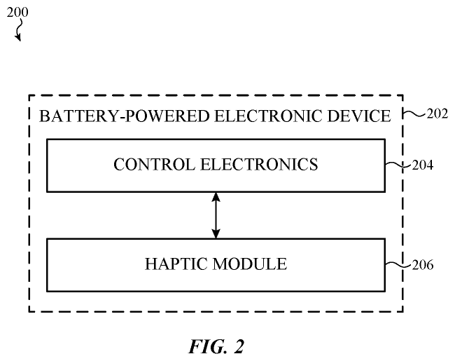

FIG. 2 depicts a system diagram of a battery-operated electronic device incorporating a haptic module. The system diagram 200 depicts a battery-powered accessory electronic device 202 that includes appropriate digital control electronics, collectively identified as the control electronics 204, that can cause actuation of a haptic module 206. The battery-powered accessory electronic device 202 may be a stylus device such as shown and described in respect of FIG. 1.

The control electronics 204 can include a processor and a memory and one or more communications modules, such as a Bluetooth module. The control electronics 204 can further include suitable control electronics to control and/or operate a power management system as described herein.

In many embodiments a processor of the control electronics 204 can cooperate with a memory of the control electronics 204 to instantiate an instance of firmware suitable to control, coordinate, or perform one or more operations of the battery-powered accessory electronic device 202. For example, the processor and memory can cooperate to sample one or more sensors of the battery-powered accessory electronic device 202 (e.g., accelerometer, gyroscope, force/pressure sensor, and so on) and/or may be configured to sample and/or be interrupted by a button press should the control electronics 204 include one or more hardware buttons that can be engaged by a user.

The processor and memory of the control electronics 204 can likewise be configured to select one or more assets from an asset store or other memory structure to playback via the haptic module 206. In particular, the control electronics 204 can be configured to store one or more assets, each of which can cause the haptic module 206 to generate a different haptic response. In some cases, a first asset and a second asset result in a similar or identical waveform but for a scaling factor distinguishing the two by amplitude. In other cases, all assets may be substantially different from one another.

As noted above, the battery-powered accessory electronic device 202 can include a power management system as described herein. The power management system can include a large capacity output capacitor interposing a current-limiting voltage regulator and a waveform generator responsible for generating one or more waveforms to drive the haptic module 206. In these examples, the control electronics 204 can be configured to determine whether the output capacitor is suitably charged (e.g., a voltage across the output capacitor matches output voltage of the current-limiting voltage regulator) before permitting playback of a particular asset.

More specifically, the control electronics 204 can be configured in some embodiments to determine, based on a current state of an output capacitor of a power management system of the battery-powered accessory electronic device 202 as described herein, to determine what assets can be replayed and what assets cannot be replayed at a given time. In this manner, the control electronics 204 can operate as a security check to ensure that an asset requiring peak power is not replayed before the output capacitor has sufficient charge to support such playback.

In many examples, however, the foregoing security function of the control electronics 204 may not be required if assets are thoughtfully designed and capacity of the output capacitor is selected so as to recharge quickly. More generally, it may be appreciated that a capacity of an output capacitor as described herein can vary from embodiment to embodiment and can be selected so as to prevent overdraw by operation of the haptic module 206.

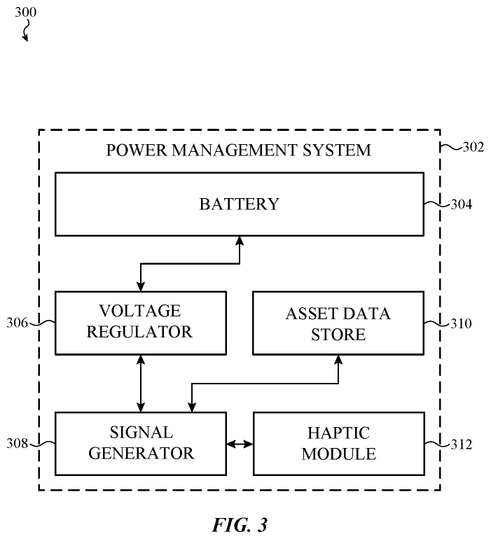

FIG. 3 depicts a system diagram of a battery-powered accessory input device incorporating a haptic module and a power management system as described herein. The schematic 300 depicts a power management system 302 as described herein. As with other embodiments, the power management system 302 receives power from a battery 304, which may be any suitable battery or group of batteries. In many cases, the battery 304 may be a rechargeable lithium based battery, but this is not required of all embodiments.

The battery 304 can be conductively coupled to a current-limiting voltage regulator 306. The current-limiting voltage regulator 306 may be a boost converter in many embodiments. For example, if the battery 304 is configured to provide a constant 3.7V as output, the current-limiting voltage regulator 306 may be configured to step up the voltage to 5.0V. Other voltages may be suitable in other embodiments.

The current-limiting voltage regulator 306 is configured to provide a supply rail for one or more digital or analog circuits of the power management system 302, such as the control electronics 204 of FIG. 2. The supply rail can be referenced to a system ground.

Output of the current-limiting voltage regulator 306 can be provided as input to a signal generator 308 which may be a digital to analog converter or a Class D amplifier. The signal generator 308 can be configured to communicably couple to an asset data store 310 or other memory structure that stores one or more assets (e.g., voltage waveforms) for playback by a haptic module. Specifically the signal generator 308 can be configured to retrieve from the asset data store 310 (and/or receive from the asset data store 310), a data item that causes the signal generator 308 to generate a suitable voltage-modulated signal to drive a haptic module 312.

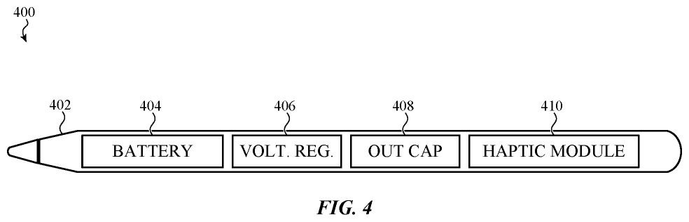

For example, FIG. 4 depicts an example battery-powered accessory device including a power management system configured to drive a haptic module at peak power. In this example, the stylus device 400 includes a housing 402 which can take a small, cylindrical in some embodiments, form factor. The housing 402 can accommodate a battery 404, a current-limiting voltage regulator 406, an output capacitor 408 and a haptic module 410.

In this example, voltage output from the battery 404 can be stepped up to a system supply rail voltage by the current-limiting voltage regulator 406. Regulated direct current output of the current-limiting voltage regulator 406 can be used to charge the output capacitor 408, that couples between the supply rail and system ground. Once charged, the output capacitor 408 can provide a suitable energy store to permit the haptic module 410 to be operated at peak power. More specifically, the output capacitor 408 can supplement power output from the current-limiting voltage regulator 406 to the extent that instantaneous current draw if the haptic module 410 exceeds the current carrying capacity of the battery 404 or the current limit of the current-limiting voltage regulator 406.

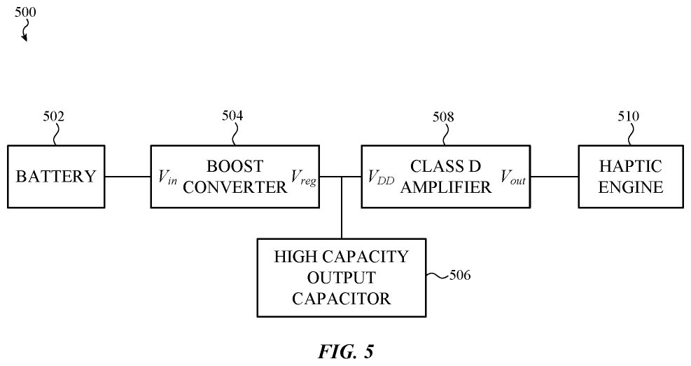

FIG. 5 depicts a simplified schematic diagram of a battery-operated electronic device power system, such as the system depicted in FIGS. 3-4. The system depicted supports peak power drive modes of a haptic module despite current output limitations of a battery and/or a boost converter.

The schematic 500 depicts a primary power source of a battery 502 that provides input to, as with other embodiments, a current-limiting boost converter 504. The current-limiting boost converter 504 can be configured to provide a regulated voltage output suitable for use as a reference voltage and constant voltage supply for low current digital and analog circuits of an electronic device incorporating the same. In the illustrated embodiment, regulated voltage output of the current-limiting boost converter 504 is supported and/or buffered by a high capacity output capacitor 506, thereafter provided as a supply input to a Class D amplifier 508 that can be used to drive a haptic engine or haptic module, such as the haptic engine 510.

In this architecture, the high capacity output capacitor 506 accommodates instantaneous current requirements of the haptic engine 510 for assets that require peak power delivery. In other words, the high capacity output capacitor 506 prevents brownout conditions from occurring should the haptic engine 510 cause voltage to drop from the current-limiting boost converter 504 or the battery 502.

These foregoing embodiments depicted in FIGS. 2-5 and the various alternatives thereof and variations thereto are presented, generally, for purposes of explanation, and to facilitate an understanding of various configurations and constructions of a power management system that can be used by a small form factor electronic device, such as described herein. However, it will be apparent to one skilled in the art that some of the specific details presented herein may not be required in order to practice a particular described embodiment, or an equivalent thereof.

Thus, it is understood that the foregoing and following descriptions of specific embodiments are presented for the limited purposes of illustration and description. These descriptions are not targeted to be exhaustive or to limit the disclosure to the precise forms recited herein. To the contrary, it will be apparent to one of ordinary skill in the art that many modifications and variations are possible in view of the above teachings.

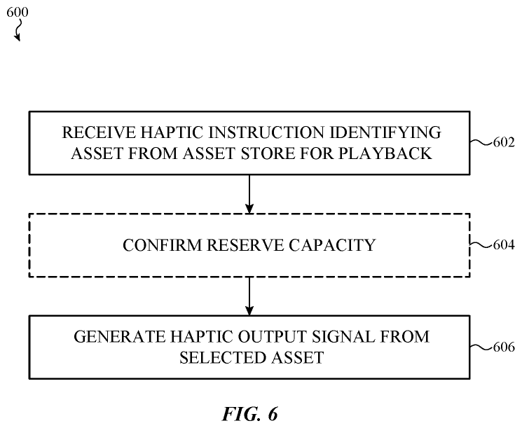

FIG. 6 depicts a simplified schematic diagram of a battery-operated electronic device power system supporting peak power drive modes of a haptic module. The method 600 can be performed by any suitable combination of hardware or software. In many cases, the method 600 is executed in whole or in part by a processor of a stylus device, such as described herein. The method 600 includes the operation 602 at which a haptic instruction is received (e.g., via a communication link with another electronic device, such as a tablet device) identifying a particular asset for playback by a haptic element. Next, optionally, at operation 604, a processor may determine whether the output capacitor (or output capacitor bank, in some embodiments) has sufficient capacity to provide suitable power to supplement output from a battery and voltage regulation circuit. Finally, at operation 606, a waveform may be generated in respect of the selected asset and applied as input to a low impedance element of the haptic module.

As used herein, the phrase “at least one of” preceding a series of items, with the term “and” or “or” to separate any of the items, modifies the list as a whole, rather than each member of the list. The phrase “at least one of” does not require selection of at least one of each item listed; rather, the phrase allows a meaning that includes at a minimum one of any of the items, and/or at a minimum one of any combination of the items, and/or at a minimum one of each of the items. By way of example, the phrases “at least one of A, B, and C” or “at least one of A, B, or C” each refer to only A, only B, or only C; any combination of A, B, and C; and/or one or more of each of A, B, and C. Similarly, it may be appreciated that an order of elements presented for a conjunctive or disjunctive list provided herein should not be construed as limiting the disclosure to only that order provided.

One may appreciate that although many embodiments are disclosed above, that the operations and steps presented with respect to methods and techniques described herein are meant as exemplary and accordingly are not exhaustive. One may further appreciate that alternate step order or fewer or additional operations may be required or desired for particular embodiments.

Although the disclosure above is described in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more embodiments, whether or not such embodiments are described and whether or not such features are presented as being a part of a described embodiment. Thus, the breadth and scope of the present description should not be limited by any of the above-described exemplary embodiments but is instead defined by the claims herein presented.

As described herein, the term “processor” refers to any software and/or hardware-implemented data processing device or circuit physically and/or structurally configured to instantiate one or more classes or objects that are purpose-configured to perform specific transformations of data including operations represented as code and/or instructions included in a program that can be stored within, and accessed from, a memory. This term is meant to encompass a single processor or processing unit, multiple processors, multiple processing units, analog or digital circuits, or other suitably configured computing element or combination of elements.

As described herein, the term “memory” refers to any software and/or hardware-implemented data storage device or circuit physically and/or structurally configured to store data in a non-transitory or otherwise nonvolatile, durable manner. This term is meant to encompass memory devices, memory device arrays (e.g., redundant arrays and/or distributed storage systems), electronic memory, magnetic memory, optical memory, and so on.

What is claimed is:

1. An electronic device comprising:
a housing;
a haptic element within the housing;
a battery within the housing; and
a power management system within the housing and comprising:
a current-limiting voltage regulator coupled to an output of the battery and configured to provide a constant voltage supply rail as output;
an output capacitor coupling the constant voltage supply rail to system ground; and
a waveform generator conductively coupled to the output capacitor and the current-limiting voltage regulator and configured to generate a voltage waveform to drive the haptic element, wherein a capacity of the output capacitor prevents the constant voltage supply rail from dropping below a threshold voltage when the haptic element is driven by the current-limiting voltage waveform.

2. The electronic device of claim 1, wherein the current-limiting voltage regulator comprises a boost converter.

3. The electronic device of claim 1, wherein the output capacitor has a capacity greater than 50 microfarads.

4. The electronic device of claim 1, wherein the waveform generator comprises a Class D amplifier.

5. The electronic device of claim 4, wherein the Class D amplifier comprises an output conductively coupled to an input of an electromagnetic coil of the haptic element.

6. The electronic device of claim 1, wherein:
the housing comprises a cylindrical portion; and
the output capacitor is sized to fit within the cylindrical portion.

7. The electronic device of claim 6, wherein the electronic device is a stylus device.

8. The electronic device of claim 1, wherein the threshold voltage is selected based on a voltage requirement of a circuit disposed within the housing.

9. The electronic device of claim 8, wherein the voltage waveform is selected from a memory of the circuit.

10. An accessory device for providing input to a portable electronic device, the accessory device comprising:
a haptic module comprising a low impedance drive element;
a battery;
a power management system and comprising:
a current-limiting voltage regulator coupled to an output of the battery and configured to provide a constant voltage supply rail as output;
an output capacitor coupling the constant voltage supply rail to system ground and configured to prevent the constant voltage supply rail from dropping; and
a signal generator receiving a supply voltage from the output capacitor and configured to generate a voltage signal as output to drive the low impedance drive element of the haptic module.

11. The accessory device of claim 10, wherein the output capacitor is parallel to an output capacitor of the current-limiting voltage regulator.

12. The accessory device of claim 10, wherein the signal generator is configured to select the voltage signal from a memory.

13. The accessory device of claim 12, wherein each voltage signal from the set of voltage signals has a duration selected at least in part on capacity of the output capacitor.

14. The accessory device of claim 10, wherein the current-limiting voltage regulator is configured to regulate voltage output of the battery above an input voltage threshold of the processor.

15. The accessory device of claim 14, wherein the current-limiting voltage regulator comprises a boost converter.

16. The accessory device of claim 10, wherein the low impedance drive element comprises an electromagnetic coil.

17. The accessory device of claim 10, wherein the portable electronic device is a tablet device and the accessory device comprises a stylus.

18. A method of driving a haptic module comprising:
receiving a first constant voltage from a battery as input to a current-limiting boost converter;
providing a second constant voltage from the current-limiting boost converter, the second constant voltage selected to exceed a minimum voltage requirement of a processor conductively coupled to the second constant voltage;
charging an output capacitor with the second constant voltage;
providing voltage across the output capacitor as supply voltage to a Class D amplifier;
providing output of the Class D amplifier as input to a haptic module; and
causing the Class D amplifier to provide an output voltage signal to drive the haptic module.

19. The method of claim 18, wherein the haptic module comprises an electromagnetic coil.

20. The method of claim 18, wherein a capacity of the output capacitor is selected to provide the output voltage signal to the haptic module without the first constant voltage falling below the minimum voltage requirement.
